(19) United States
(12) Patent Application Publication
(10) Pub. No.: US 2026/0256024 A1
(43) Pub. Date: Aug. 27, 2026

(54) SEMICONDUCTOR STRUCTURE

(71) Applicant: Powerchip Semiconductor Manufacturing Corporation, Hsinchu (TW)

(72) Inventors: Pei-Rong Ni, Hsinchu (TW); Chun-Lin Lu, Hsinchu City (TW)

(73) Assignee: Powerchip Semiconductor Manufacturing Corporation, Hsinchu (TW)

(21) Appl. No.: 19/090,422

(22) Filed: Mar. 26, 2025

(30) Foreign Application Priority Data
Feb. 21, 2025 (TW) 114106451

(51) Int. Cl. H01L 23/00; H01L 25/18

(52) U.S. Cl. CPC H10W 90/00; H10W 90/722; H10W 90/792

(57) ABSTRACT

A semiconductor structure including a carrier wafer and chips is provided. The chips are stacked on the carrier wafer. Two adjacent chips are bonded to each other. Each of the chips includes memory arrays and input/output (I/O) circuits. The I/O circuits are located aside the memory arrays. Two adjacent I/O circuits are mirror-symmetrical.

### CROSS-REFERENCE TO RELATED APPLICATION

This application claims the priority benefit of Taiwan application serial no. 114106451 filed on Feb. 21, 2025. The entirety of the above-mentioned patent application is hereby incorporated by reference herein and made a part of this specification.

### BACKGROUND

### Technical Field

The invention relates to a semiconductor structure, and particularly relates to a semiconductor structure including memory arrays and input/output circuits.

### Description of Related Art

The integrated circuit can be manufactured on the semiconductor wafer. The semiconductor wafers and/or chips can be stacked or bonded to form a the 3DIC. However, how to improve the process efficiency of the 3DIC and reduce the bonding defect and the bonding time are the goals of continues efforts.

### SUMMARY

The invention provides a semiconductor structure, which can improve the process efficiency of the 3DIC and reduce the bonding defect and the bonding time.

The invention provides a semiconductor structure including a carrier wafer and chips. The chips are stacked on the carrier wafer. Two adjacent chips are bonded to each other. Each of the chips includes memory arrays and input/output (I/O) circuits. The I/O circuits are located aside the memory arrays. Two adjacent I/O circuits are mirror-symmetrical.

According to an embodiment of the invention, in the semiconductor structure, the carrier wafer may be a controller wafer.

According to an embodiment of the invention, in the semiconductor structure, the memory arrays may be dynamic random access memory (DRAM) arrays.

According to an embodiment of the invention, in the semiconductor structure, the I/O circuits may be located between the memory arrays.

According to an embodiment of the invention, in the semiconductor structure, each of the chips may further include decoders. Each of the decoders is located between the corresponding I/O circuit and the corresponding memory array.

According to an embodiment of the invention, in the semiconductor structure, each of the chips may further include multiplexers. Each of the multiplexers is located between the corresponding I/O circuit and the corresponding decoder.

According to an embodiment of the invention, in the semiconductor structure, the chip closest to the carrier wafer may be bonded to the carrier wafer.

According to an embodiment of the invention, in the semiconductor structure, the front side of the chip closest to the carrier wafer may be bonded to the front side of the carrier wafer.

According to an embodiment of the invention, in the semiconductor structure, the interface between the chip closest to the carrier wafer and the carrier wafer may be a hybrid bonding interface.

According to an embodiment of the invention, in the semiconductor structure, the interface between the chip closest to the carrier wafer and the carrier wafer may be a bump bonding interface.

According to an embodiment of the invention, in the semiconductor structure, the back side of one of the two adjacent chips may be bonded to the back side of the other of the two adjacent chips.

According to an embodiment of the invention, in the semiconductor structure, the front surface of one of the two adjacent chips may be bonded to the front surface of the other of the two adjacent chips.

According to an embodiment of the invention, in the semiconductor structure, the front side of one of the two adjacent chips may be bonded to the back side of the other of the two adjacent chips.

According to an embodiment of the invention, in the semiconductor structure, the interface between the two adjacent chips may be a hybrid bonding interface.

According to an embodiment of the invention, in the semiconductor structure, the interface between the two adjacent chips may be a bump bonding interface.

According to an embodiment of the invention, in the semiconductor structure, the stack structure of the chip closest to the carrier wafer and the carrier wafer may be a wafer-on-wafer (WoW) stack structure.

According to an embodiment of the invention, in the semiconductor structure, the stack structure of the chip closest to the carrier wafer and the carrier wafer may be a chip-on-wafer (CoW) stack structure.

According to an embodiment of the invention, in the semiconductor structure, the stack structure of the chips may be a WoW stack structure.

According to an embodiment of the invention, in the semiconductor structure, the stack structure of the chips may be a chip-on-chip (CoC) stack structure.

According to an embodiment of the invention, in the semiconductor structure, the stack structure of the chips and the carrier wafer may be a WoW stack structure.

Based on the above description, in the semiconductor structure according to the invention, since the two adjacent I/O circuits are mirror-symmetrical, the chip design can be simplified by the mirror-symmetrical I/O circuits, and the mirror-symmetrical I/O circuits can be applicable to various bonding methods (e.g., face-to-face (F2F) bonding method, back-to-back (B2B) bonding method, and face-to-back (F2B) bonding method) and stacking methods (e.g., wafer-on-wafer (WoW) stacking). Therefore, the semiconductor structure according to the invention can improve the process efficiency of the 3DIC and reduce the bonding defect and the bonding time.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a semiconductor structure according to some embodiments of the invention.

FIG. 2 is a top view of a chip according to some embodiments of the invention.

FIG. 3 is a top view of a chip according to other embodiments of the invention.

FIG. 4 is a schematic diagram of a semiconductor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

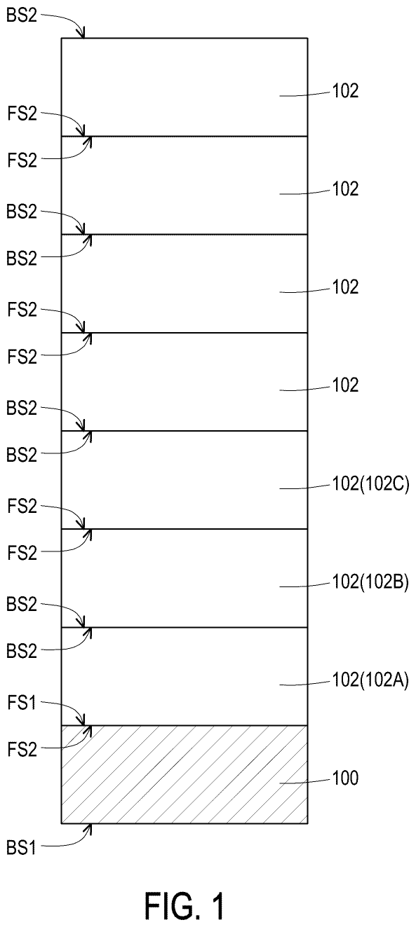

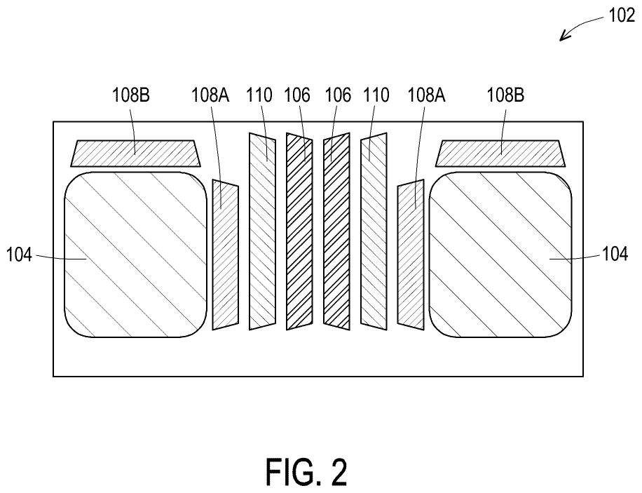

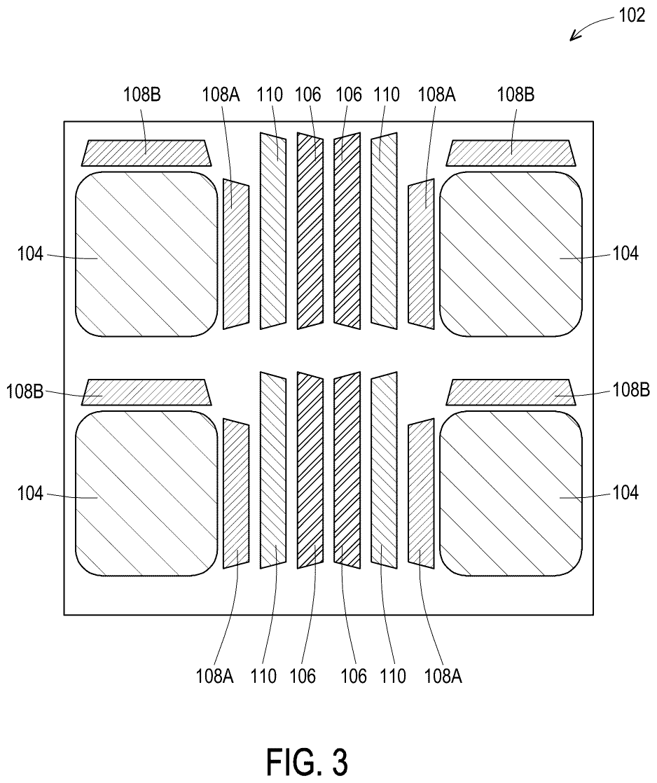

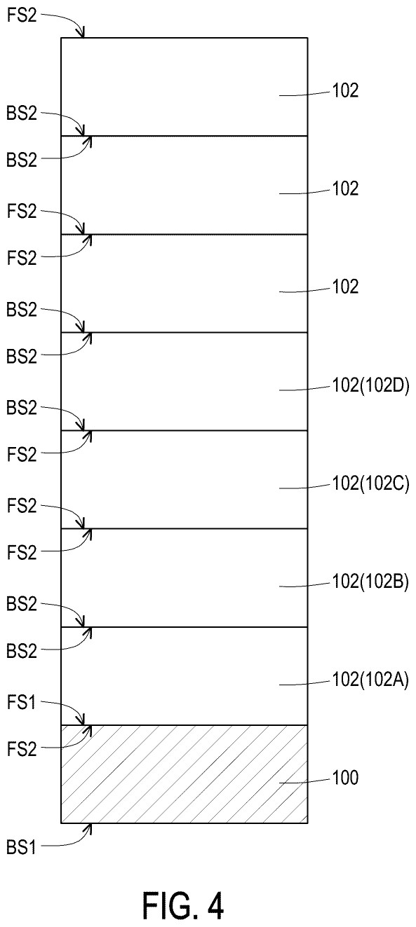

FIG. 1 is a schematic diagram of a semiconductor structure according to some embodiments of the invention. FIG. 2 is a top view of a chip according to some embodiments of the invention. FIG. 3 is a top view of a chip according to other embodiments of the invention. FIG. 4 is a schematic diagram of a semiconductor structure according to other embodiments of the invention.

Referring to FIG. 1 and FIG. 2, a semiconductor structure 10 includes a carrier wafer 100 and chips 102. The carrier wafer 100 may include a front side FS1 and a back side BS1 opposite to each other. In some embodiments, the front side FS1 may be defined as a side on which a semiconductor device (e.g., a controller) is disposed. In some embodiments, the carrier wafer 100 may be a controller wafer. That is, the controller (not shown) in the semiconductor structure 10 may be disposed in the carrier wafer 100. In some embodiments, the controller may be located on the front side FS1 of the carrier wafer 100. In FIG. 1, the components (e.g., controller) located on the carrier wafer 100 are omitted to simplify the diagram.

The chips 102 are stacked on the carrier wafer 100. Two adjacent chips 102 are bonded to each other. Each of the chips 102 includes memory arrays 104 and I/O circuits 106. Each of the chip 102 may include a front side FS2 and a back side BS2 opposite to each other. In some embodiments, the front side FS2 may be defined as a side on which semiconductor devices (e.g., memory arrays 104 and I/O circuits 106) are disposed. In some embodiments, the memory arrays 104 may be DRAM arrays. The I/O circuits 106 are located aside the memory arrays 104. In some embodiments, the I/O circuits 106 may be located between the memory arrays 104. Two adjacent I/O circuits 106 are mirror-symmetrical. Therefore, the design of the chip 102 can be simplified by the mirror-symmetrical I/O circuits 106, and the mirror-symmetrical I/O circuits 106 can be applicable to various bonding methods (e.g., face-to-face (F2F) bonding method, back-to-back (B2B) bonding method, and face-to-back (F2B) bonding method) and stacking methods (e.g., wafer-on-wafer (WoW) stacking). In addition, the number of the chips 102 is not limited to the number shown in the figure. As long as the number of the chips 102 is plural, it falls within the scope of the invention.

In some embodiments, each of the chips 102 may further include decoders 108A. Each of the decoders 108A is located between the corresponding I/O circuit 106 and the corresponding memory array 104. In some embodiments, each of the chips 102 may further include a decoder 108B. The decoder 108A and the decoder 108B may be located on different sides of the memory array 104. In some embodiments, the decoder 108B is not located between the I/O circuit 106 and the memory array 104. Each of the chips 102 may further include multiplexers 110. Each of the multiplexers 110 is located between the corresponding I/O circuit 106 and the corresponding decoder 108A. In addition, the number of the memory arrays 104, the number of the I/O circuits 106, the number of the decoders 108A, the number of the decoders 108B, and the number of the multiplexers 110 are not limited to the number shown in FIG. 2. As long as the number of the memory arrays 104, the number of the I/O circuits 106, the number of the decoders 108A, the number of the decoders 108B, and the number of the multiplexers 110 are plural, it falls within the scope of the invention. In some other embodiments, the number of the memory arrays 104, the number of the I/O circuits 106, the number of the decoders 108A, the number of the decoders 108B, and the number of the multiplexers 110 may be the number shown in FIG. 3. In addition, in FIG. 2 and FIG. 3, the same or similar components are denoted by the same reference symbols, and the description thereof is omitted.

In some embodiments, the chip 102A closest to the carrier wafer 100 may be bonded to the carrier wafer 100. In some embodiments, the method of bonding the chip 102A closest to the carrier wafer 100 to the carrier wafer 100 may be a face-to-face (F2F) bonding method. That is, the front side FS2 of the chip 102A closest to the carrier wafer 100 may be bonded to the front side FS1 of the carrier wafer 100.

In some embodiments, the method of bonding the chip 102A closest to the carrier wafer 100 to the carrier wafer 100 may be a hybrid bonding method or a bump bonding method. That is, the interface between the chip 102A closest to the carrier wafer 100 and the carrier wafer 100 may be a hybrid bonding interface or a bump bonding interface.

In some embodiments, the method of bonding the two adjacent chips 102 may be a back-to-back (B2B) bonding method. For example, as shown in FIG. 1, the back side BS2 of one of the two adjacent chips 102 (e.g., chip 102B) may be bonded to the back side BS2 of the other of the two adjacent chips 102 (e.g., chip 102A). In some embodiments, the method of bonding the two adjacent chips 102 may be a face-to-face (F2F) bonding method. For example, as shown in FIG. 1, the front side FS2 of one of the two adjacent chips 102 (e.g., chip 102C) may be bonded to the front side FS2 of the other of the two adjacent chips 102 (e.g., chip 102B). In other embodiments, the method of bonding the two adjacent chips 102 may be a face-to-back (F2B) bonding method. For example, as shown in FIG. 4, the front side FS2 of one of the two adjacent chips 102 (e.g., chip 102D) may be bonded to the back side BS2 of the other of the two adjacent chips 102 (e.g., chip 102C). In addition, in FIG. 1 and FIG. 4, the same or similar components are denoted by the same reference symbols, and the description thereof is omitted.

In some embodiments, the method of bonding the two adjacent chips 102 may be a hybrid bonding method or a bump bonding method. That is, the interface between the two adjacent chips 102 may be a hybrid bonding interface or a bump bonding interface.

In some embodiments, the chip 102 may be a chip on a wafer (i.e., a chip that has not been cut from a wafer) or a chip that has been cut from a wafer. In some embodiments, the stack structure of the chip 102A closest to the carrier wafer 100 and the carrier wafer 100 may be a WoW stack structure. In other embodiments, the stack structure of the chip 102A closest to the carrier wafer 100 and the carrier wafer 100 may be a CoW stack structure. In some embodiments, the stack structure of the chips 102 may be a WoW stack structure. In other embodiments, the stack structure of the chips 102 may be a CoC stack structure. When the stack structure of the chip 102A closest to the carrier wafer 100 and the carrier wafer 100 is a WoW stack structure, and the stack structure of the chips 102 is a WoW stack structure, the stack structure of the chips 102 and the carrier wafer 100 may be a WoW stack structure.

Based on the above embodiments, in the semiconductor structure 10, since the two adjacent I/O circuits 106 are mirror-symmetrical, the design of the chip 102 can be simplified by the mirror-symmetrical I/O circuits 106, and the mirror-symmetrical I/O circuits 106 can be applicable to various bonding methods (e.g., face-to-face (F2F) bonding method, back-to-back (B2B) bonding method, and face-to-back (F2B) bonding method) and stacking methods (e.g., wafer-on-wafer (WoW) stacking). Therefore, the semiconductor structure 10 of the above embodiments can improve the process efficiency of the 3DIC and reduce the bonding defect and the bonding time.

In summary, the semiconductor structure of the aforementioned embodiments includes a carrier wafer and chips. The chips are stacked on the carrier wafer. Two adjacent chips are bonded to each other. Each of the chips includes memory arrays and I/O circuits. The I/O circuits are located aside the memory arrays. Two adjacent I/O circuits are mirror-symmetrical. Therefore, the chip design can be simplified by the mirror-symmetrical I/O circuits, and the mirror-symmetrical I/O circuits can be applicable to various bonding methods and stacking methods. In this way, the semiconductor structure of the aforementioned embodiments can improve the process efficiency of the 3DIC and reduce the bonding defect and the bonding time.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a carrier wafer; and
chips stacked on the carrier wafer, wherein
two adjacent chips are bonded to each other,
each of the chips comprises memory arrays and input/output (I/O) circuits,
the I/O circuits are located aside the memory arrays, and
two adjacent I/O circuits are mirror-symmetrical.

2. The semiconductor structure according to claim 1, wherein the carrier wafer comprises a controller wafer.

3. The semiconductor structure according to claim 1, wherein the memory arrays comprise dynamic random access memory arrays.

4. The semiconductor structure according to claim 1, wherein the I/O circuits are located between the memory arrays.

5. The semiconductor structure according to claim 1, wherein each of the chips further comprises:
decoders, wherein each of the decoders is located between the corresponding I/O circuit and the corresponding memory array.

6. The semiconductor structure according to claim 5, wherein each of the chips further comprises:
multiplexers, wherein each of the multiplexers is located between the corresponding I/O circuit and the corresponding decoder.

7. The semiconductor structure according to claim 1, wherein the chip closest to the carrier wafer is bonded to the carrier wafer.

8. The semiconductor structure according to claim 1, wherein a front side of the chip closest to the carrier wafer is bonded to a front side of the carrier wafer.

9. The semiconductor structure according to claim 1, wherein an interface between the chip closest to the carrier wafer and the carrier wafer comprises a hybrid bonding interface.

10. The semiconductor structure according to claim 1, wherein an interface between the chip closest to the carrier wafer and the carrier wafer comprises a bump bonding interface.

11. The semiconductor structure according to claim 1, wherein a back side of one of the two adjacent chips is bonded to a back side of the other of the two adjacent chips.

12. The semiconductor structure according to claim 1, wherein a front side of one of the two adjacent chips is bonded to a front side of the other of the two adjacent chips.

13. The semiconductor structure according to claim 1, wherein a front side of one of the two adjacent chips is bonded to a back side of the other of the two adjacent chips.

14. The semiconductor structure according to claim 1, wherein an interface between the two adjacent chips comprises a hybrid bonding interface.

15. The semiconductor structure according to claim 1, wherein an interface between the two adjacent chips comprises a bump bonding interface.

16. The semiconductor structure according to claim 1, wherein a stack structure of the chip closest to the carrier wafer and the carrier wafer comprises a wafer-on-wafer stack structure.

17. The semiconductor structure according to claim 1, wherein a stack structure of the chip closest to the carrier wafer and the carrier wafer comprises a chip-on-wafer stack structure.

18. The semiconductor structure according to claim 1, wherein a stack structure of the chips comprises a wafer-on-wafer stack structure.

19. The semiconductor structure according to claim 1, wherein a stack structure of the chips comprises a chip-on-chip stack structure.

20. The semiconductor structure according to claim 1, wherein a stack structure of the chips and the carrier wafer comprises a wafer-on-wafer stack structure.
